(19) United States
(12) Patent Application Publication
(10) Pub. No.: US 2020/0227556 A1
(43) Pub. Date: Jul. 16, 2020

(54) DEVICE, METHOD AND SYSTEM FOR IMPOSING TRANSISTOR CHANNEL STRESS WITH AN INSULATION STRUCTURE

(71) Applicant: INTEL CORPORATION, Santa Clara, CA (US)

(72) Inventor: Rishabh Mehandru, Portland, OR (US)

(73) Assignee: INTEL CORPORATION, Santa Clara, CA (US)

(21) Appl. No.: 16/637,215

(22) PCT Filed: Sep. 29, 2017
(86) PCT No.: PCT/US17/54626

§ 371 Date: Feb. 6, 2020

(51) Int. Cl. H01L 29/78; H01L 27/088; H01L 21/02; H01L 21/3115; H01L 21/8234

(52) U.S. Cl. CPC H01L 29/7843; H01L 27/0886; H01L 21/823431; H01L 21/02164; H01L 21/3115; H01L 21/0217

(57) ABSTRACT

Techniques and mechanisms for imposing stress on transistors using an insulator. In an embodiment, an integrated circuit device includes a fin structure on a semiconductor substrate, wherein respective structures of two transistors are variously in or on the fin structure. A recess of the IC device, located in a region between the two transistors, extends at least partially through the fin structure. An insulator in the recess imposes stresses on respective channel regions of the two transistors. In another embodiment, compressive stresses or tensile stresses are imposed on the transistors with both the insulator and a buffer layer under the fin structure.

### BACKGROUND

### 1. Technical Field

Embodiments of the invention relate generally to semiconductor technology and more particularly, but not exclusively, to strained transistors.

### 2. Background Art

In semiconductor processing, transistors are typically formed on semiconductor wafers. In CMOS (complimentary metal oxide semiconductor) technology, transistors usually belong to one of two types: NMOS (negative channel metal oxide semiconductor) or PMOS (positive channel metal oxide semiconductor) transistors. The transistors and other devices may be interconnected to form integrated circuits (ICs) which perform numerous useful functions.

Operation of such ICs depends at least in part on the performance of the transistors, which in turn can be improved by an imposition of strain in channel regions. Specifically, performance of a NMOS transistor is improved by providing a tensile strain in its channel region, and performance of a PMOS transistor is improved by providing a compressive strain in its channel region.

A FinFET is a transistor built around a thin strip of semiconductor material (generally referred to as the fin). The transistor includes the standard field effect transistor (FET) nodes, including a gate, a gate dielectric, a source region, and a drain region. The conductive channel of such a device resides on the outer sides of the fin beneath the gate dielectric. Specifically, current runs along/within both sidewalls of the fin (sides perpendicular to the substrate surface) as well as along the top of the fin (side parallel to the substrate surface). Because the conductive channel of such configurations essentially resides along the three different outer, planar regions of the fin, such a FinFET design is sometimes referred to as a trigate FinFET. Other types of FinFET configurations are also available, such as so-called double-gate FinFETs, in which the conductive channel principally resides only along the two sidewalls of the fin (and not along the top of the fin). There are a number of non-trivial issues associated with fabricating such fin-based transistors.

### BRIEF DESCRIPTION OF THE DRAWINGS

The various embodiments of the present invention are illustrated by way of example, and not by way of limitation, in the figures of the accompanying drawings and in which:

FIG. 1 shows various views illustrating elements of an integrated circuit to promote transistor stress according to an embodiment.

FIG. 2 is a flow diagram illustrating elements of a method for promoting stress in a channel of a transistor according to an embodiment.

FIGS. 3A, 3B show cross-sectional views each illustrating structures at a respective stage of semiconductor fabrication processing according to an embodiment.

FIGS. 4A, 4B show cross-sectional views each illustrating structures at a respective stage of semiconductor fabrication processing according to an embodiment.

FIG. 5 is a functional block diagram illustrating a computing device in accordance with one embodiment.

FIG. 6 is a functional block diagram illustrating an exemplary computer system, in accordance with one embodiment.

### DETAILED DESCRIPTION

In various embodiments, apparatuses and methods relating to stressed transistors are described. Briefly, some embodiments variously promote channel stress to enhance the performance of one or more NMOS transistors and/or one or more PMOS transistors. However, various embodiments may be practiced without one or more of the specific details, or with other methods, materials, or components. In other instances, well-known structures, materials, or operations are not shown or described in detail to avoid obscuring aspects of various embodiments. Similarly, for purposes of explanation, specific numbers, materials, and configurations are set forth in order to provide a thorough understanding of some embodiments. Nevertheless, some embodiments may be practiced without specific details. Furthermore, it is understood that the various embodiments shown in the figures are illustrative representations and are not necessarily drawn to scale.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, embodiments may be employed in any of a variety of electronic devices including one or more transistors including structures formed according to techniques described herein.

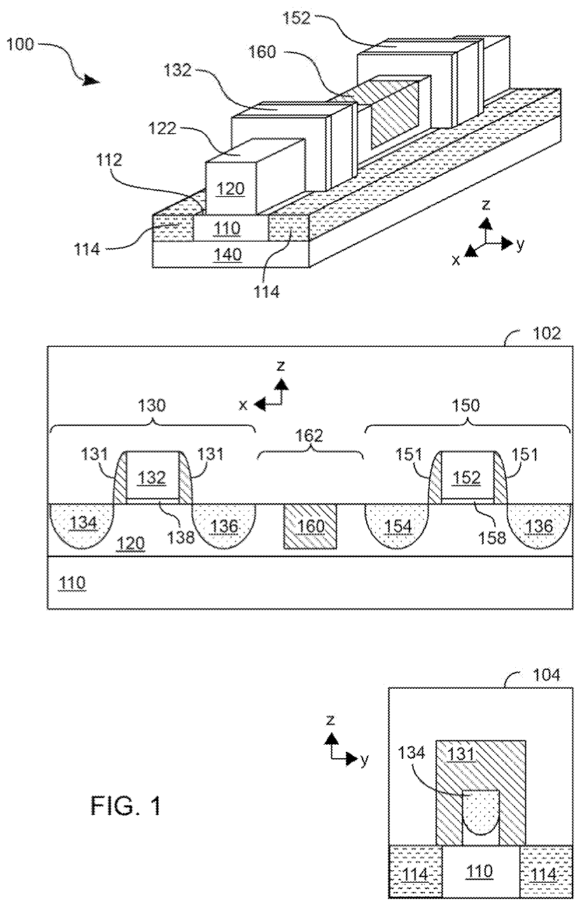

FIG. 1 shows in perspective view an integrated circuit (IC) device 100 including structures to impose stress on one or more transistors according to an embodiment. FIG. 1 also shows a cross-sectional side view 102 and a cross-sectional end view 104 of IC device 100.

IC device 100 is one example of an embodiment wherein a fin structure has disposed therein an insulator which is disposed between two transistors, where the insulator imposes stress on one or both of said two transistors. The fin structure may further comprise respective doped source or drain regions of the transistors, wherein respective gate structures of the transistors variously extend over the fin structure. The fin structure may be formed by a first semiconductor body which is disposed on a second semiconductor body (referred to herein as a “buffer layer”) that is to facilitate an imposition of stress on the transistors. The insulator may further promote the imposition of such stress.

In the example embodiment shown, IC device 100 includes a buffer layer 110 having a side 112. Buffer layer 110 may comprise one or more epitaxial single crystalline semiconductor layers (e.g., silicon, germanium, silicon germanium, gallium arsenide, indium phosphide, indium gallium arsenide, aluminum gallium arsenide, etc.) which—for example—may be grown atop a different bulk semiconductor substrate (such as the illustrative silicon substrate 140 shown).

Although some embodiments are not limited in this regard, buffer layer 110 may comprise various epitaxially grown semiconductor sub-layers having different lattice constants. Such semiconductor sub-layers may serve to grade the lattice constant along the z-axis of the xyz coordinate system shown. For example, a germanium concentration of the SiGe buffer layers 110 may increase from 30% germanium at the bottom-most buffer layer to 70% germanium at the top-most buffer layer, thereby gradually increasing the lattice constant.

IC device 100 may further include on buffer layer 110 a first semiconductor body which forms a fin structure (such as the illustrative fin structure 120 shown). For example, the first semiconductor body may be formed in part from an epitaxially grown single crystalline semiconductor such as, but not limited to Si, Ge, GeSn, SiGe, GaAs, InSb, GaP, GaSb, InAlAs, InGaAs, GaSbP, GaAsSb, GaN, GaP, and InP. Fin structure 120 may extend to side 112, in some embodiments. In other embodiments, the first semiconductor body may further comprise an underlying sublayer portion from which fin structure 120 extends (e.g., where the underlying sublayer portion is disposed between, and adjoins each of, side 112 and fin structure 120).

As used herein, “source or drain region” (or alternatively, “source/drain region”) refers to a structure which is configured to function as one of a source of a transistor or a drain of a transistor. Doped portions of fin structure 120 may provide respective sources of transistors and respective drains of the transistors. Said transistors may further comprise gate structures which variously extend over fin structure 120. In the illustrative embodiment shown, IC device 100 includes transistors 130, 150, wherein a region 162 between transistors 130, 150 includes an insulator 160 that extends at least in part in fin structure 120. Insulator 160 may extend only partially through fin structure 120 or, alternatively, may further extend to (and in some embodiments, at least partially into) buffer layer 110.

Transistor 130 may comprise doped source/drain regions 134, 136 of fin structure 120, as well as a gate dielectric 138 and a gate electrode 132 which each extend over fin structure 120. Similarly, transistor 150 may comprise doped source/drain regions 154, 156 of fin structure 120, as well as a gate dielectric 158 and a gate electrode 152 each extend over fin structure 120. Features described herein with respect to transistor 130 (e.g., features of source/drain regions 134, 136, gate dielectric 138 and gate electrode 132) may additionally pertain to transistor 150 (e.g., to source/drain regions 154, 156, gate dielectric 158 and gate electrode 152, respectively).

A channel region of transistor 130 may be disposed between source/drain regions 134, 136, wherein a gate dielectric 138 and a gate electrode 132 variously extend over a portion of fin structure 120 which includes the channel region. For example, source/drain regions 134, 136 regions may extend under laterally opposite sides of gate electrode 132.

Source/drain regions 134, 136 and the channel region may be configured to conduct current during operation of IC device 100—e.g., the current controlled using gate electrode 132. For example, source/drain regions 134, 136 may be disposed in a source/drain well which is formed with fin structure 120. Source/drain regions 134, 136 may include any of a variety of suitable n-type dopants, such as one of phosphorus or arsenic. Alternatively, source/drain regions 134, 136 may include any of various suitable p-type dopant, such as boron.

Structures of buffer layer 110 and/or structures of fin structure 120 may be electrically isolated at least in part, by insulation structures 114 (for example), from other circuit structures of IC device 100. Insulation structures 114 may include silicon dioxide or any of a variety of other dielectric materials adapted, for example, from conventional isolation techniques. The sizes, shapes, number and relative configuration of insulation structures 114 are merely illustrative, and IC device 100 may include any of a variety of additional or alternative insulation structures, in other embodiments.

Gate dielectric 138 may include a high-k gate dielectric, such as hafnium oxide. In various other embodiments, gate dielectric 138 may include hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide aluminum oxide, lead scandium tantalum oxide, or lead zinc niobate. In another embodiment, gate dielectric 138 includes silicon dioxide.

Gate electrode 132 may be formed of any suitable gate electrode material. In an embodiment, gate electrode 132 comprises a doped polycrystalline silicon. Alternatively or in addition, gate electrode 132 may comprise a metal material, such as but not limited to tungsten, tantalum, titanium and their nitrides. It is to be appreciated that gate electrode 132 need not necessarily be a single material and may be a composite stack of thin films, such as but not limited to a polycrystalline silicon/metal electrode or a metal/polycrystalline silicon electrode.

Dielectric sidewall spacers 131 may be formed at opposite sidewalls of the gate electrode 132—e.g., wherein spacers 131 comprise silicon nitride, silicon oxide, silicon oxynitride or combinations thereof. The respective thicknesses of sidewall spacers 131 may facilitate isolation of gate electrode 132 during processes to form source/drain regions 134, 136. Similarly, dielectric sidewall spacers 151 may be formed at opposite sidewalls of the gate electrode 152—e.g., to facilitate isolation of gate electrode 152 during processes to form source/drain regions 154, 156.

Although some embodiments are not limited in this regard, the transistor may include multiple distinct channel regions each between source/drain regions 134, 136—e.g., the multiple channel regions including one or more nanowire structures. Such one or more nanowires may, for example, be formed of any of various suitable materials such as, but not limited to Si, Ge, SiGe, GaAs, InSb, GaP, GaSb, InAlAs, InGaAs, GaSbP, GaAsSb, InP, and carbon nanotubes.

In an embodiment, the first semiconductor body which forms fin structure 120 may have a crystalline structure other than that of the adjoining buffer layer 110. A mismatch (e.g., the lattice constant mismatch) between fin structure 120 and side 112 may result in a compressive stress or tensile stress being imposed in a channel region which is between source/drain regions 134, 136. For example, a lattice constant of side 112 may be different from the lattice constant of fin structure 120. In one such embodiment, one of side 112 and fin structure 120 comprises silicon germanium having a first silicon-to-germanium component ratio, where the other of side 112 and fin structure 120 comprises pure silicon or silicon germanium having a second silicon-to-germanium component ratio other than the first silicon-to-germanium component ratio. However, any of various other lattice mismatches may be provided with 110 and fin structure 120, in different embodiments.

Some embodiments variously provide at least one insulator (such as the illustrative insulator 160 shown) which is located in a region between two transistors. For example, in addition to promoting electrical isolation of transistors 130, 150 from one another, insulator 160 may impose at least some mechanical stresses on transistors 130, 150. In some embodiments, insulator 160 comprises a dielectric material which has a large coefficient of thermal expansion (e.g., at least 2.0·10⁻⁷° C.⁻¹). A change in temperature after deposition of a dielectric material—and/or a subsequent doping of the deposited dielectric material—may result in insulator 160 acting as a source of stress in fin structure 120. Dielectric materials with relatively more nitrogen (N) tend to be better at enabling compressive stress, whereas dielectric materials having lower nitrogen component ratios tend to be better at enabling tensile stress.

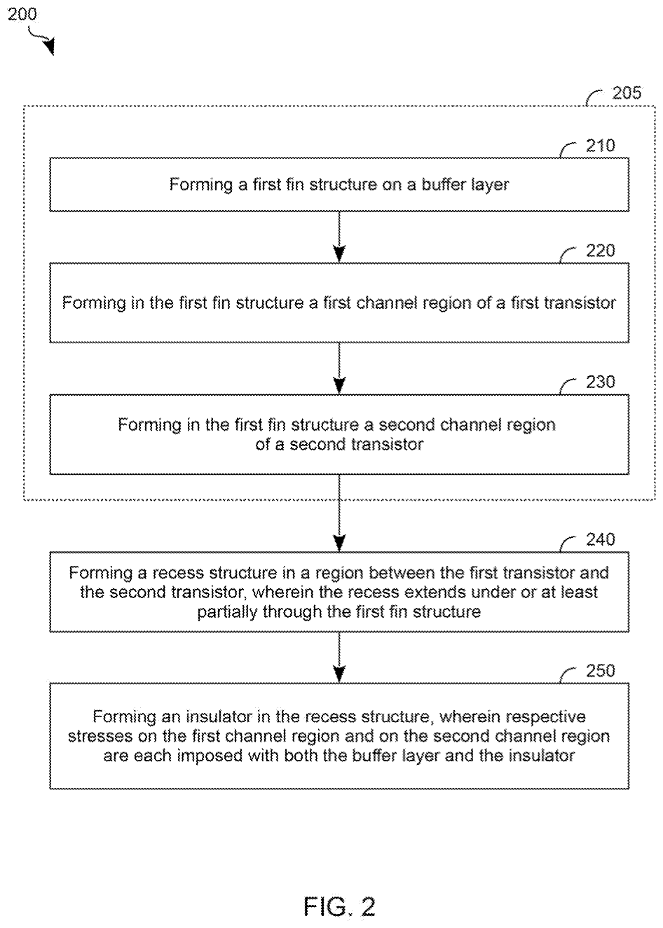

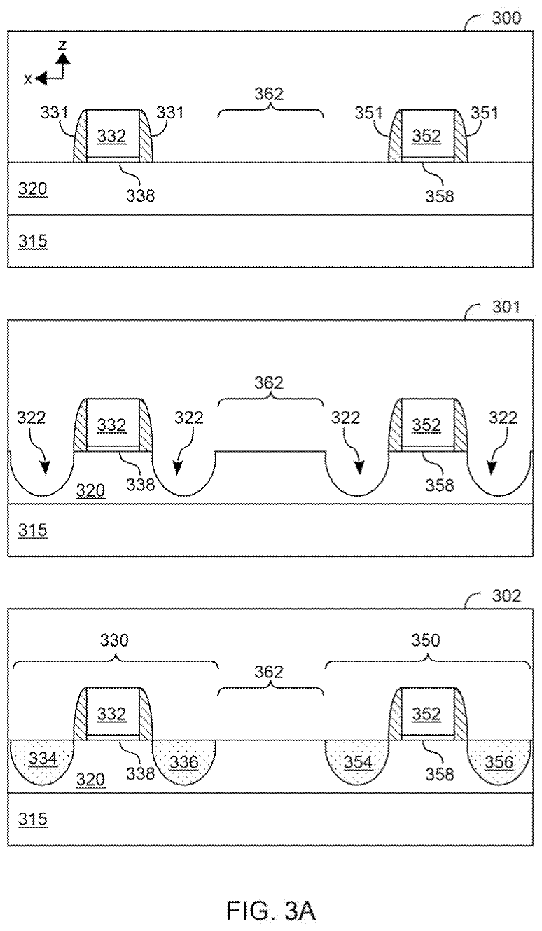

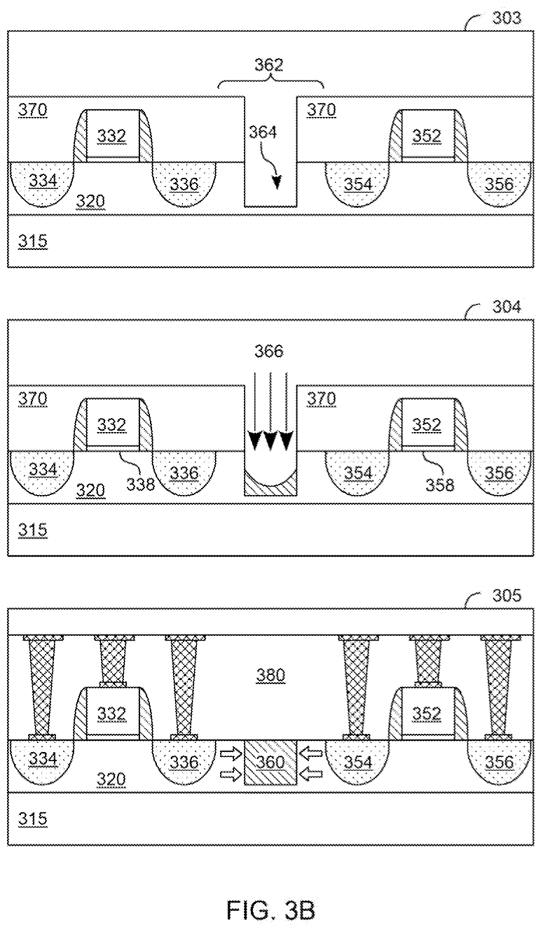

FIG. 2 shows features of a method 200 to provide a stressed channel region of a transistor according to an embodiment. Method 200 may include processes to fabricate some or all of the structure of IC device 100, for example. To illustrate certain features of various embodiments, method 200 is described herein with reference to structures shown in FIGS. 3A, 3B. However, any of a variety of additional or alternative structures may be fabricated according to method 200, in different embodiments.

As shown in FIG. 2, method 200 may include operations 205 to form two or more transistors, respective portions of which are variously formed in or on a fin structure. For example, operations 205 may include forming a first fin structure on a buffer layer (at 210) and forming in the first fin structure a first channel region of a first transistor (at 220). Operations 205 may further comprise, at 230, forming in the first fin structure a second channel region of a second transistor.

Formation of the first channel region and the second channel region may include forming in the fin structure source or drain regions which are to be variously disposed each at a respective end of one of the first channel region and the second channel region. For example, referring now to FIGS. 3A, 3B, cross-sectional side views are shown for respective stages 300-305 of processing to fabricate an insulator between transistors according to an embodiment. As shown at stage 300, a fin structure 320 may be disposed directly or indirectly on a buffer layer 315—e.g., where fin structure 320 and buffer layer 315 correspond functionally to fin structure 120 and buffer layer 110, respectively.

Respective gate dielectrics 338, 358 and gate electrodes 332, 352 of two transistors 330, 350 may be selectively formed each to variously extend at least partially around fin structure 320. Fin structure 320, gate dielectrics 338, 358, gate electrodes 332, 352 and/or other transistor structures may, for example, be formed during stages 300-305 using operations adapted from conventional semiconductor fabrication techniques—e.g., including mask, lithography, deposition (e.g., chemical vapor deposition), etching and/or other processes. Some of these conventional techniques are not detailed herein to avoid obscuring certain features of various embodiments.

Spacer portions (such as the illustrative spacer portions 331, 351 shown) may be formed—e.g., each at a respective sidewall of one of gate electrodes 332, 352. Spacers 331, 351 may be formed by blanket depositing a conformal dielectric film, such as, but not limited to, silicon nitride, silicon oxide, silicon oxynitride or combinations thereof. A dielectric material of spacers 331, 351 may be deposited in a conformal manner so that the dielectric film forms to substantially equal heights on vertical surfaces, such as the sidewalls of gate electrodes 332, 352. In one exemplary embodiment, the dielectric film is a silicon nitride film formed by a hot-wall low-pressure chemical vapor deposition (LPCVD) process. The deposited thickness of the dielectric film may determine the width or thickness of the formed spacers 331, 351. In an embodiment, the thickness of one of spacer portions 331, 351 may facilitate isolation of an adjoining one of gate electrode 332, 352 during subsequent processes to form one or more doped source/drain regions. For example, such a dielectric film may be formed to a thickness (x-axis dimension) in a range of 4 to 15 nm—e.g., wherein the thickness is in a range of 4 nm to 8 nm.

Subsequent to stage 301, one or more recess structures may be etched or otherwise formed in fin structure 320. As shown at stage 302, a wet etch and/or other subtractive processing may be performed through a patterned mask (not shown) to remove portions of fin structure 320—e.g., resulting in formation of the illustrative recesses 322 shown. Recesses 322 may be variously formed, each on a respective side of one of gate electrodes 332, 352, to allow for the subsequent deposition of a doped material of a source/drain region. For example, as shown at stage 303, a semiconductor compound may be epitaxially grown—e.g., by chemical vapor deposition (CVD) or other such additive processes at 230 of method 200—to form at least in part some or all of the illustrative source or drain regions 334, 336, 354, 356 shown. The respective semiconductor compounds of source or drain regions 334, 336, 354, 356 may include a dopant during deposition thereof or, alternatively, may be doped after deposition—e.g., using ion implantation, plasma implantation or other such doping processes.

Method 200 may further comprise, at 240, forming a recess structure in a region between the first transistor and the second transistor, wherein the recess extends under or at least partially through the first fin structure. For example, as shown at stage 303, a wet etch and/or other subtractive processing may be performed through a patterned mask 370 to remove a portion of fin structure 320—e.g., resulting in formation of the illustrative recess 364. In the example embodiment shown, recess 364 extends only partially through fin structure 320 in a (z-axis) direction toward buffer layer 315. In other embodiments, recess 364 may extend entirely through fin structure 320—e.g., wherein recess 364 extends at least partially through a semiconductor body which includes both fin structure 320 and underlying sublayer portion from which fin structure 120 extends. Recess 364—which is located in a region 362 of fin structure 320 between transistors 330, 350—may accommodate the subsequent deposition of an insulating dielectric.

Referring again to FIG. 2, method 200 may further comprise, at 250, forming an insulator in the recess structure, wherein respective stresses on the first channel region and on the second channel region are each imposed with both the buffer layer and the insulator. For example, as shown at stage 304, a deposition 366—e.g., including CVD processing—of dielectric material into recess 366 may result in the formation of an insulator 360 (shown at stage 305). Insulator 360 may extend only partially through fin structure 320 or, alternatively, may further extend to (and in some embodiments, at least partially into) buffer layer 315.

In the example embodiment shown, insulator 360 variously imposes tensile stresses via fin structure 320 each on a respective one of a channel region between source/drain regions 334, 336 and another channel region between source/drain regions 354, 356. Such tensile stress may be in combination with that imposed based on a lattice mismatch between buffer layer 315 and fin structure 320. One or more insulation structures (not shown)—e.g., including insulation structures 114—may be formed during or after stages 300-305, in some embodiments.

To promote an imposition of tensile stress with insulator 360, deposition 366 may take place, for example, while a temperature of fin structure 320 is relatively high, as compared to during later stages. By way of illustration and not limitation, fin structure 320 may be at least 300 degrees Celsius (° C.) during deposition 366 (e.g., where fin structure 320 is in a range of 300° C. to 700° C. and, in some embodiments, a range of 400° C. to 650° C.). Alternatively or in addition, the dielectric material which is to comprise insulator 360 may be relatively high temperature during deposition 366. For example, tensile strength may be promoted by the dielectric material being at least 300° C. (e.g., where the dielectric material is in a range of 300° C. to 750° C. and, in some embodiments, a range of 400° C. to 750° C.). In some embodiments, use of any of various oxide materials during deposition 366 may contribute to tensile stress. Specific examples of such oxide materials include, but are not limited to, SiₓO_{y} (of any of various stoichiometric ratios), SiO₂, Si₃O₄, SiO₂:C, SiO₂:B, and SiₓO_{y}N_{z} (where y>z).

In other embodiments, insulator 360 may instead variously impose compressive stresses on the channel regions of transistors 330, 350. Such compressive stress may be in combination with compressive stresses imposed based on a lattice mismatch between buffer layer 315 and fin structure 320. To promote an imposition of compressive stress with insulator 360, deposition 366 may take place, for example, while a temperature of fin structure 320 is relatively low, as compared to during later stages. By way of illustration and not limitation, fin structure 320 may be at or below 650° C. during deposition 366 (e.g., where fin structure 320 is in a range of 200° C. to 650° C. and, in some embodiments, a range of 300° C. to 600° C.). Alternatively or in addition, the dielectric material which is to comprise insulator 360 may be relatively low temperature during deposition 366. For example, compressive strength may be promoted by the dielectric material being at or below 650° C. (e.g., where the dielectric material is at or below 600° C.). In some embodiments, use of any of various nitride materials during deposition 366 may contribute to compressive stress. Specific examples of such nitride materials include, but are not limited to, SiₓN_{y}, Si₃N₄, Si₃N₄:N, Si₃N₄:B, Si₃N₄:C, Si₃N₄:O, SiₓO_{y}N_{z} (where y<z).

Although some embodiments are not limited in this regard, method 200 may further comprise one or more other operations (not shown) to further configure operation of the two transistors. For example, as shown at stage 305, additional structures—such as the illustrative metallization layer 380 shown—may be formed to connect transistors 330, 350 for power, signal communication or the like.

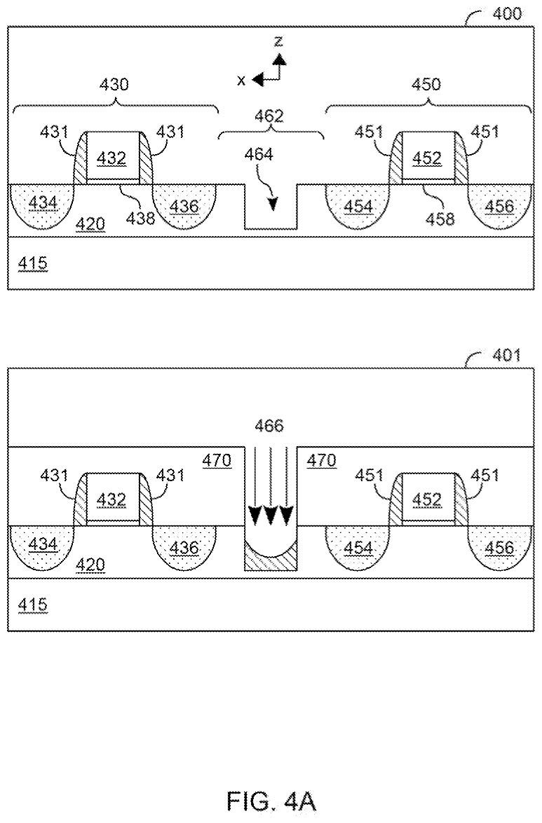

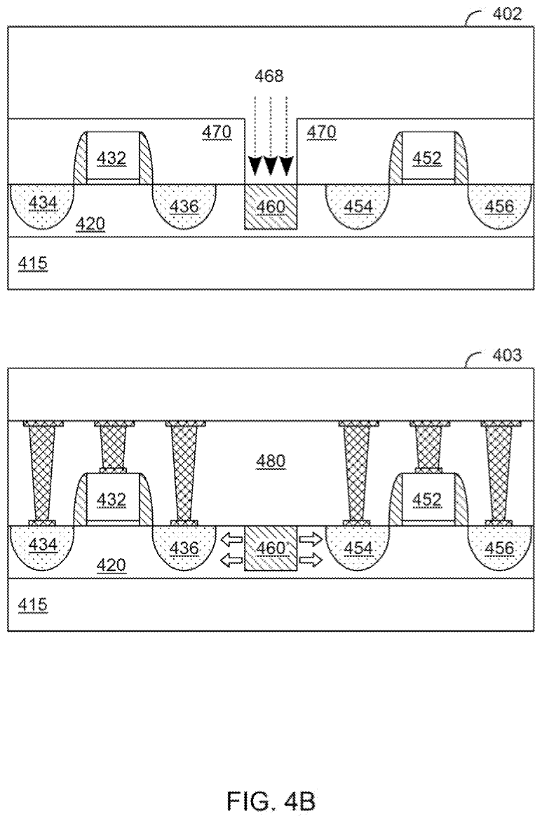

In some embodiments, forming the insulator at 250 of method 200 includes depositing a dielectric material in the recess structure and, after such depositing, doping the dielectric material to induce a compressive stress. For example, referring now to FIGS. 4A, 4B, cross-sectional side views are shown for respective stages 400-403 of processing to fabricate transistor structures according to an embodiment. Operations such as those illustrated by stages 400-403 may provide some or all of the features of IC device 100, for example.

As shown at stage 400, a fin structure 420 may be disposed directly or indirectly on a buffer layer 415—e.g., where fin structure 420 and buffer layer 415 correspond functionally to fin structure 120 and buffer layer 110, respectively. A transistor 430 may include source or drain regions 434, 436 in fin structure 420, as well as a gate electrode 432 and a gate dielectric 438 which variously extend over fin structure 420. Similarly, a transistor 450 may include source or drain regions 454, 456 in fin structure 420, as well as a gate electrode 452 and a gate dielectric 458 which variously extend over fin structure 420. A wet etch and/or other subtractive processing may be performed through a patterned mask 470 to remove a portion of fin structure 420—e.g., resulting in formation of the illustrative recess 464 in a region 462 between transistors 430, 450. The structures shown at stage 400 may, for example, have some or all of the features of those structures shown at stage 303.

Recess 464 may extend at least partially through a semiconductor body which forms fin structure 420—e.g., where (in some other embodiments) recess 464 extends entirely through fin structure 420 and at least partially through an underlying sublayer portion of the semiconductor body. Recess 464 may accommodate the subsequent deposition of an insulating dielectric. For example, as shown at stage 401, a deposition 466 of dielectric material into recess 466 may result in the formation of an insulator 460 (shown at stage 402). Some embodiments may use techniques, such as those described herein with reference to stages 300-305, to promote compressive stresses being imposed with insulator 460. Alternatively or in addition, compressive stress may be promoted by a subsequent doping 468 (at stage 402) of previously deposited dielectric material of insulator 460. Doping 468 may introduce nitrogen, argon or any of various other elements. Such dopants may result in a compressive force being imposed on transistors 430, 450 with a doped insulator 460′. In an embodiment, doped insulator 460′ extends only partially through fin structure 420 or, alternatively, further extends to (and in some embodiments, at least partially into) buffer layer 415.

Although some embodiments are not limited in this regard, method 200 may further comprise one or more other operations (not shown) to further configure operation of the two transistors. For example, as shown at stage 403, additional structures—such as the illustrative metallization layer 480 shown—may be formed to connect transistors 430, 450 for power, signal communication or the like.

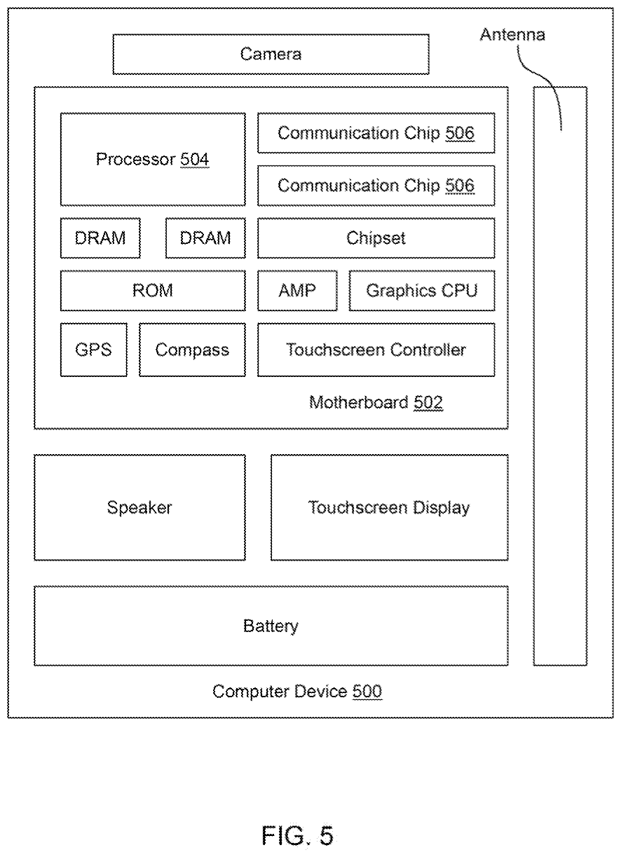

FIG. 5 illustrates a computing device 500 in accordance with one embodiment. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. The term “processor” may refer to any device or portion of a device that processes electronic data from registers and/or memory to transform that electronic data into other electronic data that may be stored in registers and/or memory. The communication chip 506 also includes an integrated circuit die packaged within the communication chip 506.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

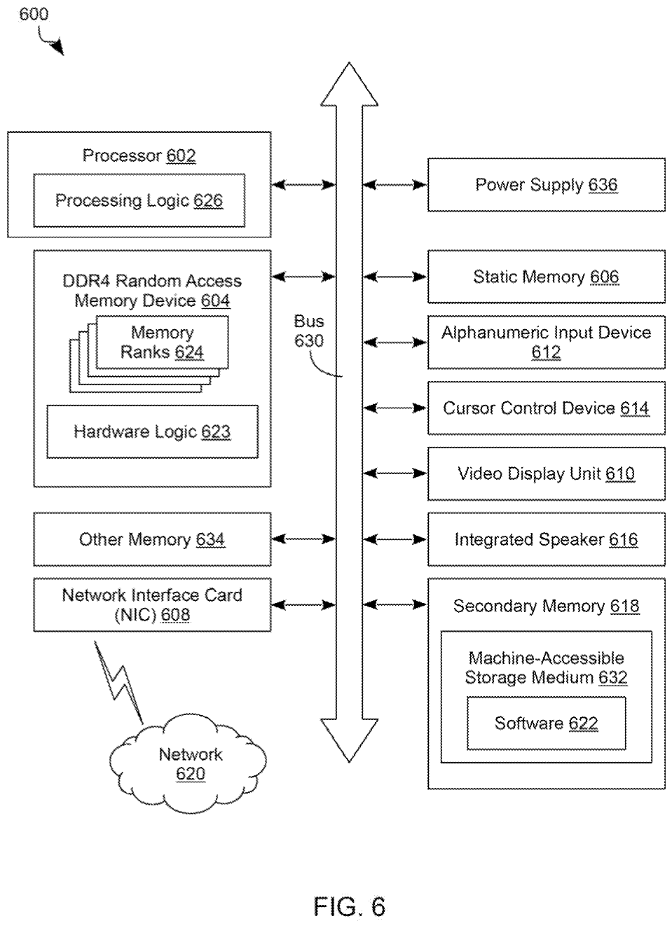

FIG. 6 illustrates a diagrammatic representation of a machine in the exemplary form of a computer system 600 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 632 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, an integrated circuit (IC) device comprises a buffer layer, a first fin structure disposed on the buffer layer, the first fin structure including a first channel region of a first transistor, a second channel region of a second transistor, a recess structure formed in a region between the first transistor and the second transistor, wherein the recess structure extends under or at least partially through the first fin structure, and an insulator disposed in the recess structure, wherein respective stresses on the first channel region and on the second channel region are each imposed with both the buffer layer and the insulator.

In one embodiment, respective compressive stresses on the first channel region and on the second channel region are each imposed with both the buffer layer and the insulator. In another embodiment, respective tensile stresses on the first channel region and on the second channel region are each imposed with both the buffer layer and the insulator. In another embodiment, the recess structure extends entirely through the first fin structure. In another embodiment, the recess structure extends to the buffer layer. In another embodiment, the insulator adjoins a source/drain region of one of the first transistor and the second transistor. In another embodiment, the IC device further comprises a second fin structure disposed on the buffer layer, wherein the recess structure and the insulator each extend under or at least partially through the second fin structure.

In another implementation, a method comprises forming a first fin structure on the buffer layer, forming in the first fin structure a first channel region of a first transistor, and a second channel region of a second transistor, forming a recess structure in a region between the first transistor and the second transistor, wherein the recess extends under or at least partially through the first fin structure, and forming an insulator in the recess structure, wherein respective stresses on the first channel region and on the second channel region are each imposed with both the buffer layer and the insulator.

In one embodiment, wherein respective compressive stresses on the first channel region and on the second channel region are each imposed with both the buffer layer and the insulator. In another embodiment, the insulator includes a nitride compound. In another embodiment, respective tensile stresses on the first channel region and on the second channel region are each imposed with both the buffer layer and the insulator. In another embodiment, the insulator includes an oxide compound. In another embodiment, the recess structure extends entirely through the first fin structure. In another embodiment, the recess structure extends to the buffer layer. In another embodiment, the insulator adjoins a source/drain region of one of the first transistor and the second transistor. In another embodiment, the method further comprises a second fin structure disposed on the buffer layer, wherein the recess structure and the insulator each extend under or at least partially through the second fin structure. In another embodiment, forming the insulator includes depositing an insulation material in the recess structure, and after the depositing, doping the insulation material to induce a compressive stress.

In another implementation, a system comprises an integrated circuit (IC) device comprising a buffer layer, a first fin structure disposed on the buffer layer, the first fin structure including a first channel region of a first transistor, and a second channel region of a second transistor, a recess structure formed in a region between the first transistor and the second transistor, wherein the recess structure extends under or at least partially through the first fin structure, and an insulator disposed in the recess structure, wherein respective stresses on the first channel region and on the second channel region are each imposed with both the buffer layer and the insulator. The system further comprises a display device coupled to the IC device, the display device to display an image based on a signal communicated with the first transistor and the second transistor.

In one embodiment, respective compressive stresses on the first channel region and on the second channel region are each imposed with both the buffer layer and the insulator. In another embodiment, respective tensile stresses on the first channel region and on the second channel region are each imposed with both the buffer layer and the insulator. In another embodiment, the recess structure extends entirely through the first fin structure. In another embodiment, the recess structure extends to the buffer layer. In another embodiment, the insulator adjoins a source/drain region of one of the first transistor and the second transistor. In another embodiment, the IC device further comprises a second fin structure disposed on the buffer layer, wherein the recess structure and the insulator each extend under or at least partially through the second fin structure.

Techniques and architectures for promoting stress in a transistor are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1-24. (canceled)

25. An integrated circuit (IC) device comprising:
a buffer layer;
a first fin structure disposed on the buffer layer, the first fin structure including:
a first channel region of a first transistor; and
a second channel region of a second transistor;
a recess structure formed in a region between the first transistor and the second transistor, wherein the recess structure extends under or at least partially through the first fin structure; and
an insulator disposed in the recess structure, wherein respective stresses on the first channel region and on the second channel region are each imposed with both the buffer layer and the insulator.

26. The IC device of claim 25, wherein respective compressive stresses on the first channel region and on the second channel region are each imposed with both the buffer layer and the insulator.

27. The IC device of claim 25, wherein respective tensile stresses on the first channel region and on the second channel region are each imposed with both the buffer layer and the insulator.

28. The IC device of claim 25, wherein the recess structure extends entirely through the first fin structure.

29. The IC device of claim 25, wherein the recess structure extends to the buffer layer.

30. The IC device of claim 25, wherein the insulator adjoins a source/drain region of one of the first transistor and the second transistor.

31. The IC device of claim 25, further comprising a second fin structure disposed on the buffer layer, wherein the recess structure and the insulator each extend under or at least partially through the second fin structure.

32. A method comprising:
forming a first fin structure on the buffer layer;
forming in the first fin structure:
a first channel region of a first transistor; and
a second channel region of a second transistor;
forming a recess structure in a region between the first transistor and the second transistor, wherein the recess extends under or at least partially through the first fin structure; and
forming an insulator in the recess structure, wherein respective stresses on the first channel region and on the second channel region are each imposed with both the buffer layer and the insulator.

33. The method of claim 32, wherein respective compressive stresses on the first channel region and on the second channel region are each imposed with both the buffer layer and the insulator.

34. The method of claim 33, wherein the insulator includes a nitride compound.

35. The method of claim 32, wherein respective tensile stresses on the first channel region and on the second channel region are each imposed with both the buffer layer and the insulator.

36. The method of claim 35, wherein the insulator includes an oxide compound.

37. The method of claim 32, wherein the recess structure extends entirely through the first fin structure.

38. The method of claim 32, wherein the recess structure extends to the buffer layer.

39. The method of claim 32, wherein the insulator adjoins a source/drain region of one of the first transistor and the second transistor.

40. The method of claim 32, further comprising a second fin structure disposed on the buffer layer, wherein the recess structure and the insulator each extend under or at least partially through the second fin structure.

41. The method of claim 32, wherein forming the insulator includes:
depositing an insulation material in the recess structure; and
after the depositing, doping the insulation material to induce a compressive stress.

42. A system comprising:
an integrated circuit (IC) device comprising:
a buffer layer;
a first fin structure disposed on the buffer layer, the first fin structure including:
a first channel region of a first transistor; and
a second channel region of a second transistor;
a recess structure formed in a region between the first transistor and the second transistor, wherein the recess structure extends under or at least partially through the first fin structure; and
an insulator disposed in the recess structure, wherein respective stresses on the first channel region and on the second channel region are each imposed with both the buffer layer and the insulator; and
a display device coupled to the IC device, the display device to display an image based on a signal communicated with the first transistor and the second transistor.

43. The system of claim 42, wherein respective compressive stresses on the first channel region and on the second channel region are each imposed with both the buffer layer and the insulator.

44. The system of claim 42, wherein respective tensile stresses on the first channel region and on the second channel region are each imposed with both the buffer layer and the insulator.
